(19) United States
(12) Patent Application Publication
(10) Pub. No.: US 2009/0068780 A1
(43) Pub. Date: Mar. 12, 2009

(54) METHOD OF FABRICATING SEMICONDUCTOR OPTOELECTRONIC DEVICE AND RECYCLING SUBSTRATE DURING FABRICATION THEREOF

(76) Inventors: Miin-Jang Chen, Taipei City (TW); Wen-Ching Hsu, Hsinchu City (TW); Suz-Hua Ho, Jhudong Township (TW)

Correspondence Address: Muncy, Geissler, Olds & Lowe, PLLC, P.O. BOX 1364, FAIRFAX, VA, 22038-1364, US

(21) Appl. No.: 12/208,772

(22) Filed: Sep. 11, 2008

(30) Foreign Application Priority Data
Sep. 12, 2007 (TW) 096134046

(51) Int. Cl. H01L 33/00

(52) U.S. Cl. 438/47; 257/E33.025

(57) ABSTRACT

The invention discloses a method of fabricating a semiconductor optoelectronic device. First, a substrate is prepared. Subsequently, a buffer layer is deposited on the substrate. Then, a multi-layer structure is deposited on the buffer layer, wherein the multi-layer structure includes an active region. The buffer layer assists the epitaxial growth of the bottom-most layer of the multi-layer structure, and the buffer layer also serves as a lift-off layer. Finally, with an etching solution, only the lift-off layer is etched to debond the substrate away from the multi-layer structure, wherein the multi-layer structure serves as the semiconductor optoelectronic device.

### BACKGROUND OF THE INVENTION

1. Field of the Invention

The present invention relates to a method of fabricating a semiconductor optoelectronic device and a method of recycling a substrate during fabrication of said semiconductor optoelectronic device.

2. Description of the Prior Art

Nowadays, semiconductor light-emitting devices, such as light-emitting diodes, have been used for a wide variety of applications, e.g. illumination and remote control.

Please refer to FIG. 1. FIG. 1 illustrates a sectional view of a semiconductor light-emitting device 1 in the prior art. The semiconductor light-emitting device 1 contains a substrate 10, a multi-layer structure 12, a first electrode 14, and a second electrode 16. It needs to be noticed that to make the semiconductor light-emitting device 1 work, the first electrode 14 is deposited on a top-most layer of the multi-layer structure 12, and the second electrode 16 is deposited on the etched portion of the multi-layer structure 12.

However, since the first electrode 14 and the second electrode 16 can not be disposed in the same vertical direction, one semiconductor light-emitting device consumes more materials. If the substrate 10 can be debonded away from a bottom-most layer (e.g. a GaN semiconductor material layer) of the multi-layer structure 12 during fabrication of the semiconductor light-emitting device 1, and the second electrode 16 can be deposited on the surface of the bottom-most layer (e.g. the first electrode 14 and the second electrode 16 are disposed in the same vertical direction), then the material required for fabrication of one semiconductor light-emitting device for a unit cell can now be used to produce two semiconductor light-emitting devices substantially.

In addition, the current semiconductor light-emitting device 1 is mainly grown on a sapphire substrate 10. However, it may lead to the shortage of the sapphire substrate 10. As a result, if the sapphire substrate 10 can be recycled during fabrication of the semiconductor optoelectronic device 1, then the sapphire substrate 10 can be utilized again to reduce manufacture cost.

In the prior art, the semiconductor optoelectronic device 1 can be illuminated by a laser, and a lift-off layer (not shown in FIG. 1) of said semiconductor optoelectronic device 1 can be decomposed by absorbing the energy of the laser such that the substrate 10 can be debonded away from the semiconductor optoelectronic device 1. However, this method costs much and is unfavorable in practical applications.

Therefore, to solve the aforementioned problem, the main scope of the invention is to provide a method of fabricating a semiconductor optoelectronic device and a method of recycling a substrate during fabrication of said semiconductor optoelectronic device.

### SUMMARY OF THE INVENTION

One scope of the invention is to provide a method of fabricating a semiconductor optoelectronic device and a method of recycling a substrate during fabrication of said semiconductor optoelectronic device.

It is related to a method of fabricating a semiconductor optoelectronic device according to an embodiment of the invention. First, a substrate is prepared. Subsequently, a buffer layer is deposited on the substrate. Then, a multi-layer structure is deposited on the buffer layer, wherein the multi-layer structure includes an active region. The buffer layer assists the epitaxial growth of a bottom-most layer of the multi-layer structure and also serves as a lift-off layer. Finally, with an etching solution, only the lift-off layer is etched to debond the substrate away from the multi-layer structure, wherein the multi-layer structure serves as the semiconductor optoelectronic device.

It is related to a method of recycling a substrate during fabrication of a semiconductor optoelectronic device according to another embodiment of the invention. The semiconductor optoelectronic device includes a substrate, a buffer layer deposited on the substrate, and a multi-layer structure deposited on the buffer layer. The multi-layer structure includes an active region. The buffer layer assists the epitaxial growth of a bottom-most layer of the multi-layer structure and also serves as a lift-off layer.

In the method, only the lift-off layer is etched to debond the substrate away from the multi-layer structure by an etching solution and to further recycle the substrate.

Compared to the prior art, according to the method of the invention, only the lift-off layer can be etched by the etching solution to debond the substrate away from the multi-layer structure by the method according to the invention, wherein the multi-layer structure can further be processed to serve as the semiconductor optoelectronic device. Besides, after the substrate is debonded away from the multi-layer structure, the substrate is further recycled to reduce the manufacture cost and economize the use of materials.

The advantage and spirit of the invention may be understood by the following recitations together with the appended drawings.

### BRIEF DESCRIPTION OF THE APPENDED DRAWINGS

FIG. 1 illustrates a semiconductor light-emitting device in the prior art.

FIGS. 2A through 2F are sectional views illustrating a method of fabricating a semiconductor optoelectronic device in accordance with an embodiment of the invention.

FIG. 3A and FIG. 3B are sectional views illustrating a method of recycling a substrate during fabrication of a semiconductor optoelectronic device in accordance with another embodiment of the invention.

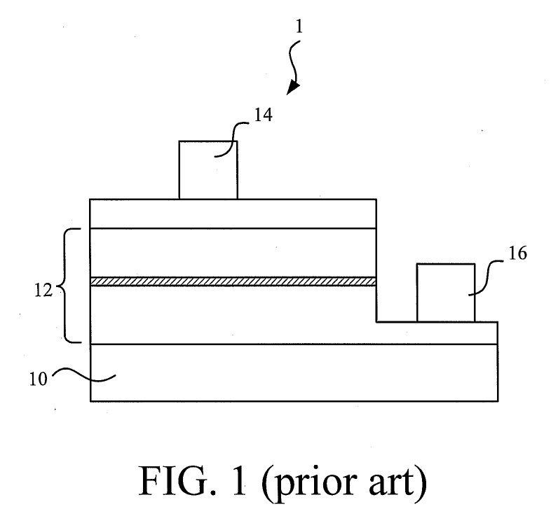

### DETAILED DESCRIPTION OF THE INVENTION

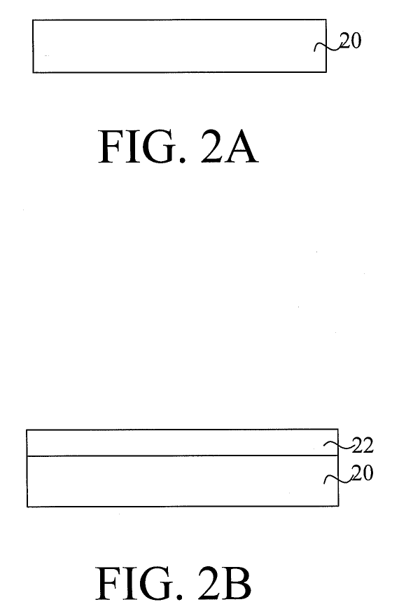

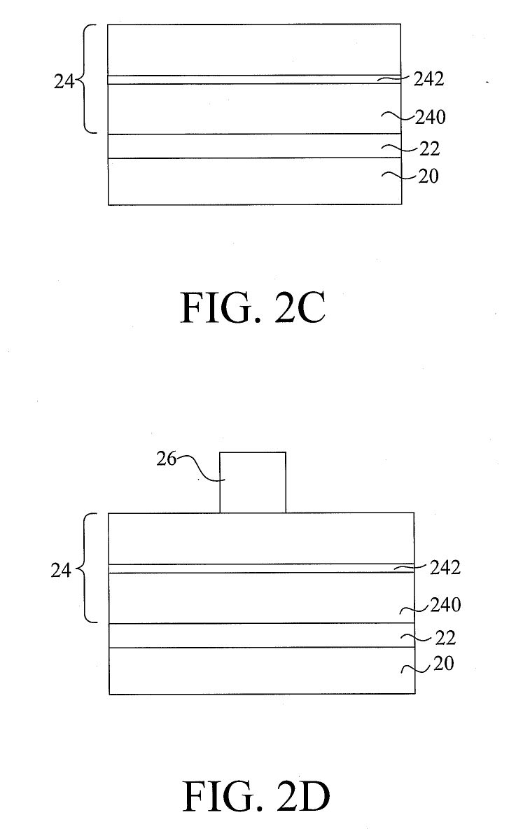

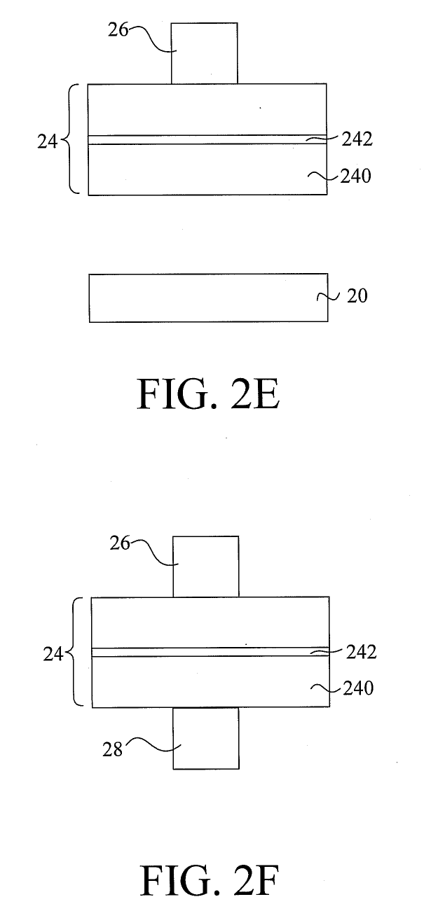

Please refer to FIGS. 2A through 2F. FIGS. 2A through 2F are sectional views illustrating a method of fabricating a semiconductor optoelectronic device in accordance with an embodiment of the invention. In this embodiment, the semiconductor optoelectronic device is illustrated by a semiconductor light-emitting device (e.g. a light-emitting diode). In practical applications, the semiconductor optoelectronic device is not limited to the semiconductor light-emitting device.

First, as shown in FIG. 2A, a substrate 20 is prepared.

In practical applications, the substrate 20 can be made of sapphire, Si, SiC, GaN, ZnO, ScAlMgO₄, YSZ (Yttria-Stabilized Zirconia), SrCu₂O₂, LiGaO₂, LiAO₂, GaAs, and the like. In this embodiment, the substrate 20 can be a sapphire substrate 20.

Subsequently, as shown in FIG. 2B, a buffer layer 22 is deposited on the substrate 20.

In practical applications, the buffer layer 22 can be made of ZnO or MgₓZn₁₋ₓO, where 0<x≦1. The buffer layer may have a thickness in a range of 10 nm to 500 nm.

In practical applications, the buffer 22 layer can be deposited by a sputtering process, an MOCVD process, an atomic layer deposition process, a plasma-enhanced atomic layer deposition process, or a plasma-assisted atomic layer deposition process. In one embodiment, if the buffer layer 22 is deposited by the atomic layer deposition process, then the deposition of the buffer layer can be performed at a processing temperature ranging from room temperature to 600° C. The buffer layer can be further annealed at a temperature ranging from 400° C. to 1200° C. after deposition.

In one embodiment, if the buffer layer 22 is deposited by the atomic layer deposition process, and the buffer layer 22 is formed of ZnO, then the precursors of the buffer layer 22 of ZnO can be ZnCl₂, ZnMe₂, ZnEt₂, H₂O, O₃, O₂ plasma and oxygen radicals, where the Zn element comes from ZnCl₂, ZnMe₂ or ZnEt₂; the O element comes from H₂O, O₃, O₂ plasma or oxygen radicals.

In one embodiment, if the buffer layer 22 is deposited by the atomic layer deposition process, and the buffer layer 22 is formed of MgₓZn₁₋ₓO, then the precursors of the buffer layer 22 of MgₓZn₁₋ₓO can be ZnCl₂, ZnMe₂, ZnEt₂, MgCp₂, Mg(thd)₂, H₂O, O₃, O₂ plasma and an oxygen radicals, where the Mg element comes from MgCp₂ or Mg(thd)₂ ; the Zn element comes from ZnCl₂, ZnMe₂, or ZnEt₂; the O element comes from H₂O, O₃, O₂ plasma or oxygen radicals.

Taking the deposition of the buffer layer of ZnO as an example, an atomic layer deposition cycle includes four reaction steps of:

1. Using a carrier gas to carry H₂O molecules into the reaction chamber, thereby the H₂O molecules are absorbed on the upper surface of the substrate to form a layer of OH radicals, where the exposure period is 0.1 second;

2. Using a carrier gas to purge the H₂O molecules not absorbed on the upper surface 100 of the substrate 10, where the purge time is 5 seconds;

3. Using a carrier gas to carry ZnEt₂ molecules into the reaction chamber, thereby the ZnEt₂ molecules react with the OH radicals absorbed on the upper surface of the substrate to form one monolayer of ZnO, wherein a by-product is organic molecules, where the exposure period is 0.1 second; and

4. Using a carrier gas to purge the residual ZnEt₂ molecules and the by-product due to the reaction, where the purge time is 5 seconds.

The carrier gas can be highly-pure argon or nitrogen. The above four steps, called one cycle of the atomic layer deposition, grows a thin film with single-atomic-layer thickness on the whole area of the substrate. The property is called self-limiting capable of controlling the film thickness with a precision of one atomic layer in the atomic layer deposition. Thus, controlling the number of cycles of atomic layer deposition can precisely control the thickness of the ZnO buffer layer.

In conclusion, the atomic layer deposition process adopted by the invention has the following advantages: (1) able to control the formation of the material in nano-metric scale; (2) able to control the film thickness more precisely; (3) able to have large-area production; (4) having excellent uniformity; (5) having excellent conformality; (6) pinhole-free structure; (7) having low defect density; and (8) low deposition temperature, etc.

Afterwards, as shown in FIG. 2C, a multi-layer structure 24 is deposited on the buffer layer 22.

The multi-layer structure 24 includes an active region which can be a light-emitting region 242 of the multi-layer structure 24 in this embodiment. The buffer layer 22 assists the epitaxial growth of the bottom-most layer 240 of the multi-layer structure 24 and also serves as a lift-off layer.

In practical applications, the bottom-most layer 240 can be formed of GaN, InGaN, AlN, or AlGaN. In this embodiment, the bottom-most layer 240 can be formed of GaN, and the GaN layer can be deposited by an MOCVD (metalorganic chemical vapor deposition) process or an HVPE (hydride vapor phase epitaxy) process.

Next, as shown in FIG. 2D, a first ohmic electrode structure 26 can be deposited on the multi-layer structure 24.

Then, as shown in FIG. 2E, with an etching solution, only the lift-off layer can be etched to debond the substrate 20 away from the multi-layer structure 24.

In this embodiment, if the buffer layer 22 is formed of ZnO, then the etching solution can be a hydrofluoric acid solution, a hydrochloric acid solution, or a nitric acid solution. In practical applications, the etching solution can be chosen in accordance with the material of the buffer layer 22. In principle, the etching solution can only etch the buffer layer 22 which serves as the lift-off layer.

In one embodiment, after the substrate 20 is deboded away from the multi-layer structure 24, the first ohmic electrode structure 26 can be depsoited on the multi-layer structure 24. In other words, the first ohmic electrode structure 26 can be deposited on the multi-layer structure 24 before or after the substrate 20 is deboded away from the multi-layer structure 24.

Finally, as shown in FIG. 2F, a second ohmic electrode structure 28 can be deposited on the bottom-most layer 240 (i.e. the GaN layer) of the multi-layer structure 24. As a result, the multi-layer structure 24 including the first ohmic electrode structure 26 and the second ohmic electrode structure 28 can serve as the semiconductor light-emitting device. Preferably, since the first ohmic electrode structure 26 and the second ohmic electrode structure 28 can be disposed in the same vertical direction, the yield of the semiconductor light-emitting devices fabricated on the sapphire substrate 20 can be increased greatly.

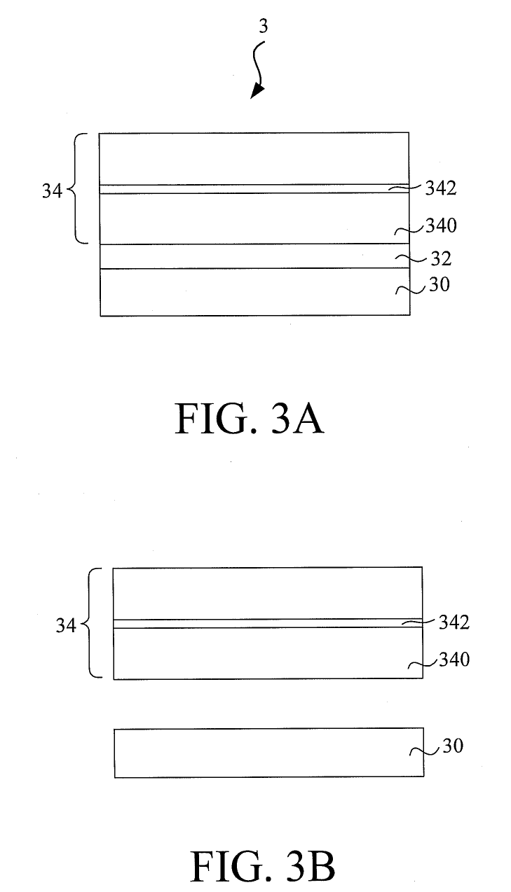

Please refer to FIG. 3A and FIG. 3B. FIG. 3A and FIG. 3B are sectional views illustrating a method of recycling a substrate 30 during fabrication of a semiconductor optoelectronic device 3 in accordance with another embodiment of the invention.

As shown in FIG. 3A, the semiconductor light-emitting device 3 includes the substrate 30, a buffer layer 32 deposited on the substrate 30, and a multi-layer structure 34 deposited on the buffer layer 32. The multi-layer structure 34 includes an active region 342. The buffer layer 32 assists the epitaxial growth of the bottom-most layer 340 of the multi-layer structure 34 and also serves as a lift-off layer.

As shown in FIG. 3B, in the method, only the lift-off layer is etched by an etching solution to debond the substrate 30 away from the multi-layer structure 34, and further to recycle the substrate 30. In practical applications, the substrate 30 can proceed to be used for producing the semiconductor light-emitting device 3 or for other purposes.

Compared to the prior art, according to the method of the invention, only the lift-off layer can be etched by the etching solution to debond the substrate away from the multi-layer structure, wherein the multi-layer structure can further be processed to serve as the semiconductor optoelectronic device. Besides, after the substrate is debonded away from the multi-layer structure, the substrate is further recycled to reduce the manufacture cost and economize the use of materials.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A method of fabricating a semiconductor optoelectronic device, comprising the steps of:
preparing a substrate;
depositing a buffer layer on the substrate;
depositing a multi-layer structure on the buffer layer, wherein the multi-layer structure comprises an active region, the buffer layer assists the epitaxial growth of a bottom-most layer of the multi-layer structure and also serves as a lift-off layer; and
with an etching solution, only etching the lift-off layer to debond the substrate away from the multi-layer structure, wherein the multi-layer structure serves as said semiconductor optoelectronic device.

2. The method of claim 1, wherein the buffer layer is formed of ZnO or MgₓZn₁₋ₓO, where 0<x≦1.

3. The method of claim 2, wherein the bottom-most layer is formed of a material selected from the group consisting of GaN, InGaN, AlN, and AlGaN.

4. The method of claim 2, wherein the etching solution is a hydrofluoric acid solution, a hydrochloric acid solution, or a nitric acid solution.

5. The method of claim 2, wherein the buffer layer is deposited by one selected from the group consisting of a sputtering process, an MOCVD (metalorganic chemical vapor deposition) process, an atomic layer deposition process, a plasma-enhanced atomic layer deposition process, and a plasma-assisted atomic layer deposition process.

6. The method of claim 3, wherein the bottom-most layer is deposited by an MOCVD process or an HVPE (hydride vapor phase epitaxy) process.

7. The method of claim 2, wherein the buffer layer has a thickness in a range of 10 nm to 500 nm.

8. The method of claim 2, wherein the substrate is formed of a material selected from the group consisting of sapphire, Si, SiC, GaN, ZnO, ScAlMgO₄, YSZ (Yttria-Stabilized Zirconia), SrCu₂O₂, LiGaO₂, LiAlO₂, and GaAs.

9. A method of recycling a substrate during fabrication of a semiconductor optoelectronic device, said semiconductor optoelectronic device comprising the substrate, a buffer layer deposited on the substrate, and a multi-layer structure deposited on the buffer layer and comprising an active region, the buffer layer assisting the epitaxial growth of a bottom-most layer of the multi-layer structure and serving as a lift-off layer, said method comprising the step of:
with an etching solution, only etching the lift-off layer to debond the substrate away from the multi-layer structure, and further to recycle the substrate.

10. The method of claim 9, wherein the buffer layer is formed of ZnO or MgₓZn₁₋ₓO, 0<x≦1.

11. The method of claim 10, wherein the bottom-most layer is formed of a material selected from the group consisting of GaN, InGaN, AlN, and AlGaN.

12. The method of claim 10, wherein the etching solution is a hydrofluoric acid solution, a hydrochloric acid solution, or a nitric acid solution.

13. The method of claim 10, wherein the buffer layer is deposited by one selected from the group consisting of a sputtering process, an MOCVD process, an atomic layer deposition process, a plasma-enhanced atomic layer deposition process, and a plasma-assisted atomic layer deposition process.

14. The method of claim 11, wherein the bottom-most layer is deposited by an MOCVD process or an HVPE process.

15. The method of claim 10, wherein the buffer layer has a thickness in a range of 10 nm to 500 nm.

16. The method of claim 10, wherein the substrate is formed of a material selected from the group consisting of sapphire, Si, SiC, GaN, ZnO, ScAlMgO₄, YSZ, SrCu₂O₂, LiGaO₂, LiAlO₂, and GaAs.
